(19) United States
(12) Patent Application Publication
(10) Pub. No.: US 2022/0167532 A1
(43) Pub. Date: May 26, 2022

(54) HEAT SINK AND ELECTRONIC COMPONENT PACKAGE

(71) Applicant: KAGA, INC., Tokyo (JP)

(72) Inventors: Yousuke NAKAMURA, Ishikawa (JP); Shu MATSUURA, Ishikawa (JP)

(73) Assignee: KAGA, INC., Tokyo (JP)

(21) Appl. No.: 17/598,053

(22) PCT Filed: Apr. 1, 2020
(86) PCT No.: PCT/JP2020/015042

§ 371 Date: Sep. 24, 2021

(30) Foreign Application Priority Data
Apr. 2, 2019 (JP) 2019-070486
Jul. 8, 2019 (JP) 2019-127174

(51) Int. Cl. H05K 7/20; F28F 13/06

(52) U.S. Cl. CPC H05K 7/20409; F28F 13/06

(57) ABSTRACT

Favorable heat dissipating performances are obtained by a simple and space-saving shape. A base part of which one side surface serves as an electronic component contact surface and the opposite side surface as a heat dissipating surface and two heat dissipating pieces provided on one end side and the other end side in a direction in which the heat dissipating surface continues in the base part are provided, each of the two heat dissipating pieces has a side wall part protruding from the heat dissipating surface and a top wall part protruding from a tip side of the side wall part toward the other heat dissipating piece and ensuring an outer space between the top wall part and the heat dissipating surface, and the two top wall parts are separated such that a ventilation path causing an inner space and the outer space to communicate with each other is ensured therebetween.

### TECHNICAL FIELD

The present invention relates to a heat sink and an electronic component package which is configured to radiate heat of an electronic component and the like.

### BACKGROUND ART

Conventionally, this type of invention, as described in PTL 1, includes a heat radiating apparatus including a base part, protruding pieces protruding upward from left and right ends of the base part, a plurality of fins protruding outward from each of the protruding pieces, and a power transistor attached onto the base part between the left and right protruding pieces and is configured in a substantially U-shape.

### CITATION LIST

### Patent Literature

[PTL 1] Japanese Utility Model Application Publication No. 59-103496 (see FIG. 1)

### SUMMARY OF INVENTION

### Technical Problem

However, according to the aforementioned prior art, since the plurality of fins protrude outward form each of the protruding pieces, an entire dimension in the horizontal direction becomes large, which requires a wide installation space. Moreover, the plurality of fins, each having a complicated shape, needs to be formed, which leaves a room for improvement in manufacture. Omission of the plurality of fins can be examined, but lowering of heat dissipating performance is concerned about.

### Solution to Problem

In view of such problems, the present invention includes the following configurations.

A heat sink including a plate-shaped base part of which one side surface serves as an electronic component contact surface and the opposite side surface as a heat dissipating surface and two heat dissipating pieces provided on one end side and the other end side in a direction in which the heat dissipating surface continues in the base part, in which each of the two heat dissipating pieces has a side wall part protruding from the heat dissipating surface and a top wall part protruding from a tip side of the side wall part toward the other heat dissipating piece and ensuring an inner space between the top wall part and the heat dissipating surface, and two of the top wall parts are separated such that a ventilation path causing the inner space and an outer space to communicate with each other is ensured therebetween.

### Advantageous Effects of Invention

The present invention is configured as above and thus, favorable heat dissipating performance can be obtained by the simple and space-saving shape.

### BRIEF DESCRIPTION OF DRAWINGS

FIG. 1 is a perspective view illustrating an example of a heat sink according to the present invention.

FIG. 2(a) is a cross sectional view along a (II)-(II) line in FIG. 1 and illustrates a horizontally set state.

FIG. 2(b) is a cross sectional view along a (II)-(II) line in FIG. 1 and illustrates a vertically set state.

FIG. 3 is a perspective view illustrating another example of the heat sink according to the present invention.

FIG. 4(a) is a cross sectional view along a (IV)-(IV) line in FIG. 3 and illustrates a horizontally set state.

FIG. 4(b) is a cross sectional view along a (IV)-(IV) line in FIG. 3 and illustrates a vertically set state.

FIG. 5 is a perspective view illustrating another example of the heat sink according to the present invention.

FIG. 6(a) is a cross sectional view along a (VI)-(VI) line in FIG. 5 and illustrates a horizontally set state.

FIG. 6(b) is a cross sectional view along a (VI)-(VI) line in FIG. 5 and illustrates a vertically set state.

FIG. 7 is a perspective view illustrating another example of the heat sink according to the present invention.

FIG. 8 is an enlarged cross sectional view along a (VIII)-(VIII) line in FIG. 7.

FIG. 9(a) is a cross sectional view along a (IX)-(IX) line in FIG. 7 and illustrates a horizontally set state.

FIG. 9(b) is a cross sectional view along a (IX)-(IX) line in FIG. 7 and illustrates a vertically set state.

FIG. 10 is a perspective view illustrating an example of a conventional heat sink.

FIG. 11 is a table illustrating a comparative experiment example of the heat sinks according to the present invention and the conventional heat sink.

FIG. 12 is a perspective view illustrating another example of the heat sink according to the present invention.

FIG. 13 is a perspective view illustrating another example of the heat sink according to the present invention.

FIG. 14 is a table illustrating an experiment example of the heat sinks shown in FIG. 12 and FIG. 13.

FIG. 15 is a perspective view illustrating another example of the heat sink according to the present invention.

FIG. 16(a) is a vertical sectional view illustrating an example of a ventilation hole and a protruding edge part.

FIG. 16(b) is a vertical sectional view illustrating an example of a protrusion.

FIG. 17 is a perspective view illustrating another example of the heat sink according to the present invention.

FIG. 18 is a perspective view illustrating another example of the heat sink according to the present invention.

FIG. 19 is a perspective view illustrating another example of the heat sink according to the present invention.

FIG. 20 is an exploded perspective view illustrating the heat sink in FIG. 19.

### DESCRIPTION OF EMBODIMENTS

In this embodiment, the following features are disclosed.

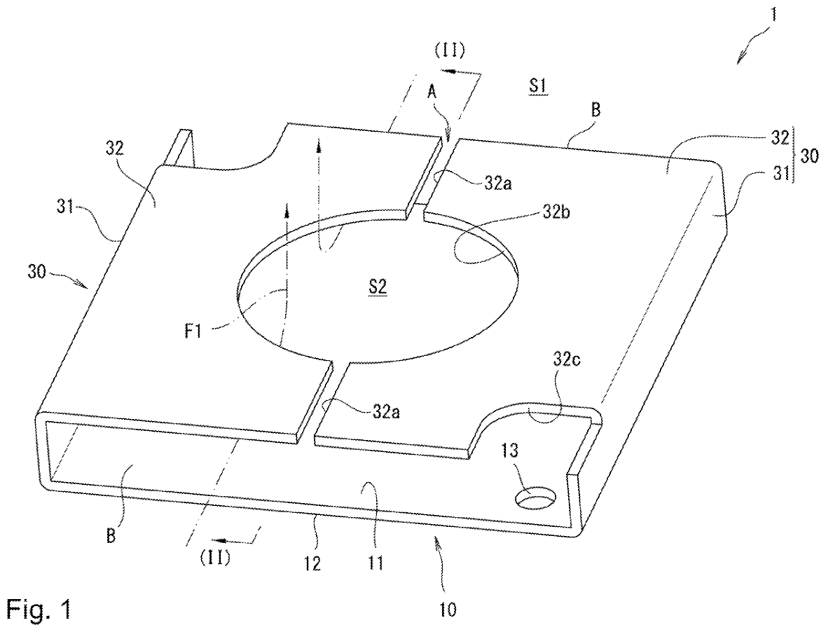

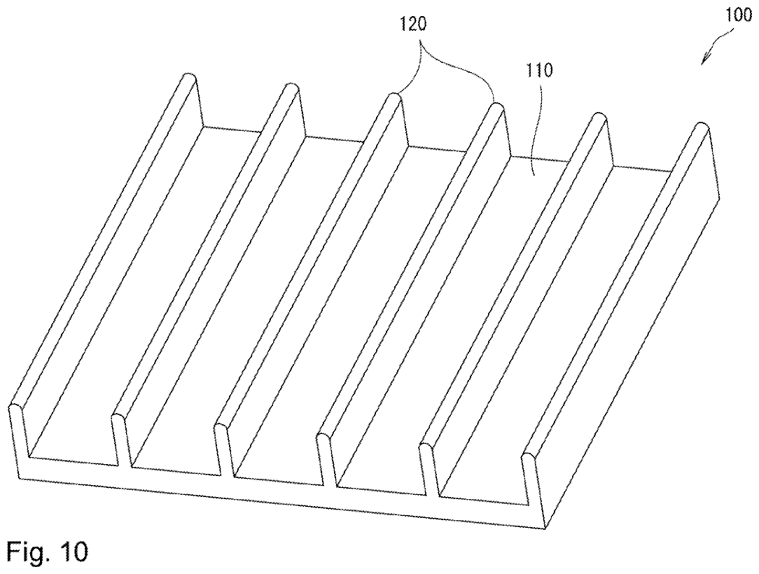

A first feature is that a base part of which one side surface serves as an electronic component contact surface and the opposite side surface as a heat dissipating surface and two heat dissipating pieces provided on one end side and the other end side in a direction in which the heat dissipating surface continues in the base part are provided, each of the two heat dissipating pieces has a side wall part protruding from the heat dissipating surface and a top wall part protruding from a tip side of the side wall part toward the other heat dissipating piece and ensuring an inner space between the top wall part and the heat dissipating surface, and two of the top wall parts are separated such that a ventilation path causing the inner space and an outer space to communicate with each other is ensured therebetween (see FIGS. 1 to 20).

As a second feature, the ventilation path includes a slit part between the two top wall parts (see FIGS. 1 to 9(b), 12 to 13, and 14 to 20.)

As a third feature, the ventilation path includes a penetrating part which has a penetrating hole shape across the two top wall parts and a width larger than the slit part (see FIGS. 1 to 9(b), 13, and 17).

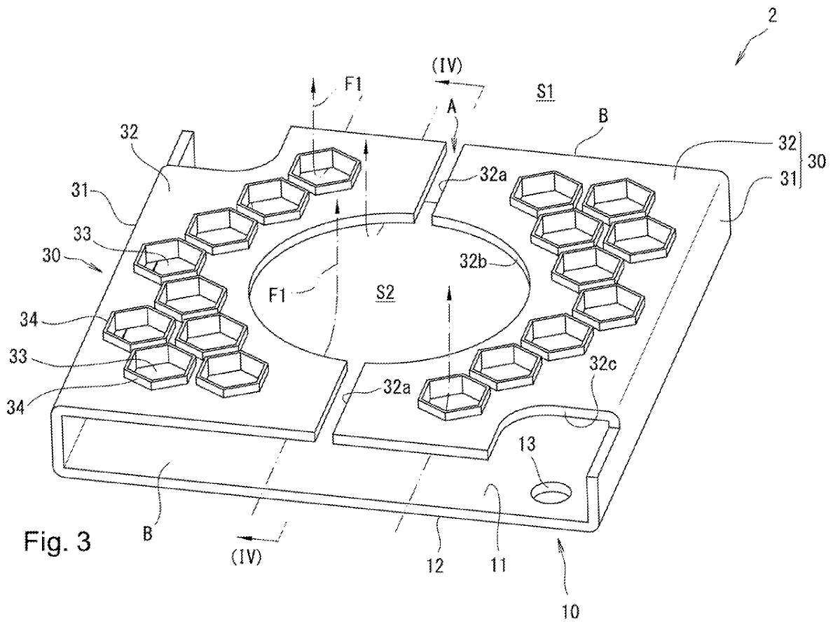

As a fourth feature, a ventilation hole which penetrates the top wall part in a thickness direction is provided in at least one of the two top wall parts (see FIGS. 3 to 6(b), 15, 16(a) and 17).

As a fifth feature, a protruding edge part protruding toward the outer space is provided on an inner edge side of the ventilation hole (see FIGS. 3 to 6(b)).

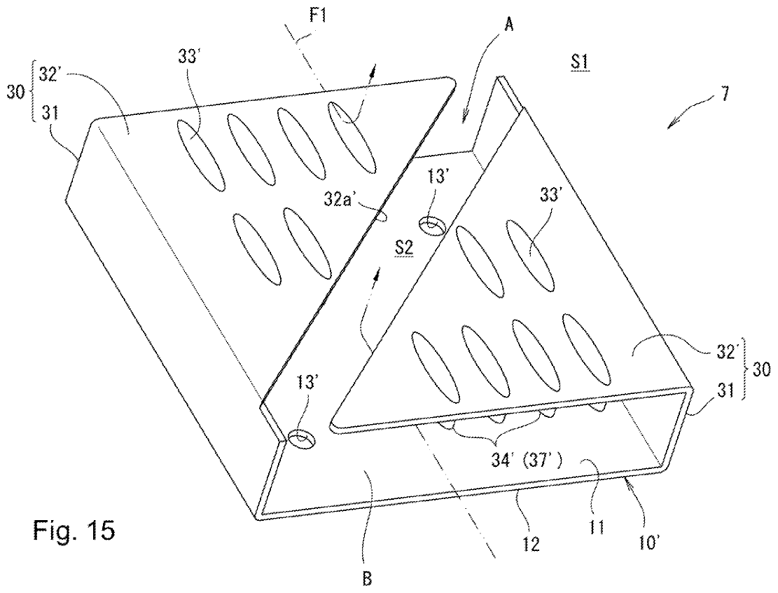

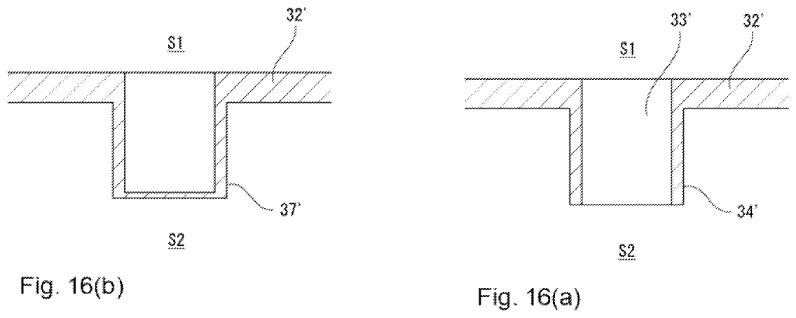

As a sixth feature, a protruding edge part protruding toward the inner space is provided on the inner edge side of the ventilation hole (see FIGS. 15 and 16(a)).

As a seventh feature, the ventilation holes and the protruding edge parts are provided in plural on each of the top wall parts, and the two adjacent protruding edge parts are disposed with a gap (see FIGS. 3 to 4(b), 15, and 17).

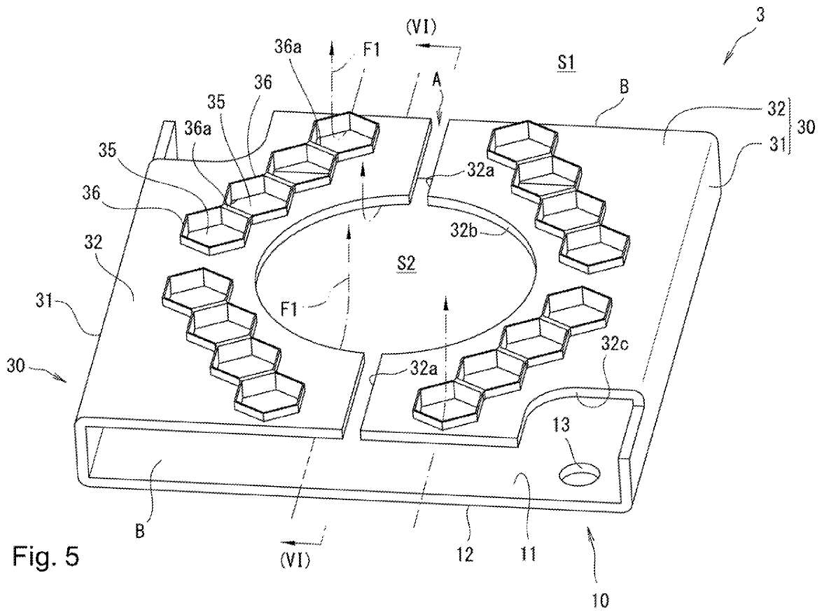

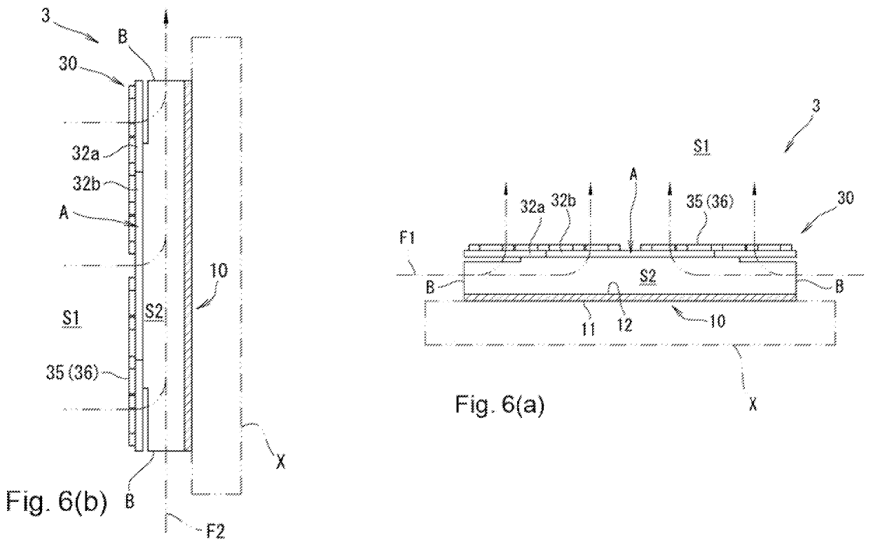

As an eighth feature, the ventilation holes and the protruding edge parts are provided in plural on each of the top wall parts, and the two adjacent protruding edge parts are configured by sharing a wall part located therebetween and to be integrated (see FIGS. 5 to 6(b)).

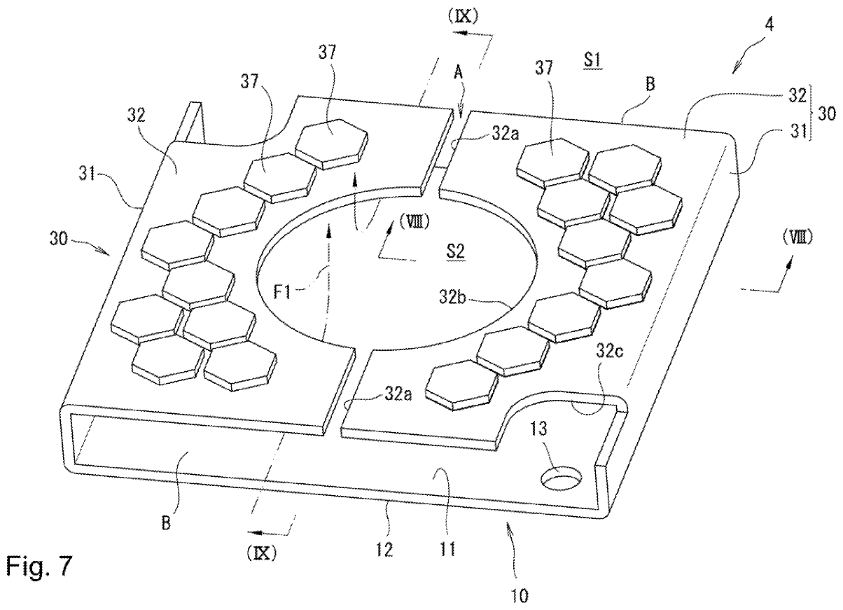

As a ninth feature, a plurality of protrusions protruding to the outer space side are provided on at least one of the two top wall parts, and each of the protrusions is formed in a bottomed tubular shape with a bottom part on the opposite side to the base part side (see FIGS. 7 to 9(b)).

As a tenth feature, a plurality of protrusions protruding to the inner space side are provided on at least one of the two top wall parts, and each of the protrusions is formed in a bottomed tubular shape with a bottom part on the base part side (see FIGS. 15 and 16(b)).

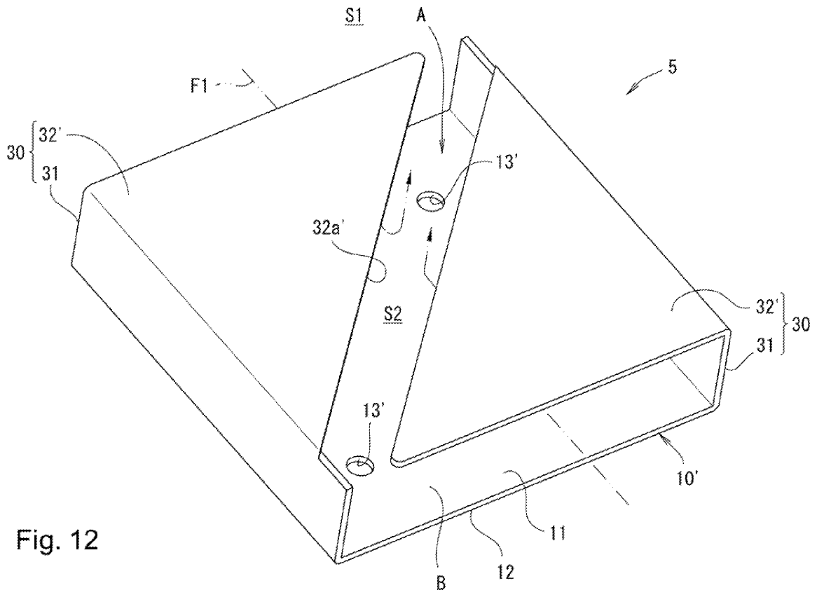

As an eleventh feature, a penetrating mounting hole is provided in the base part, and the mounting hole is provided within a range of the ventilation path on a plane view (see FIGS. 12, 13, 15, and 17 to 20).

As a twelfth feature, the top wall part of one heat dissipating piece and the top wall part of the other heat dissipating piece in the two heat dissipating pieces are formed in triangles with hypotenuses facing each other, and the ventilation path is ensured between the two hypotenuses facing each other (see FIGS. 12, 13, 15, and 17 to 20).

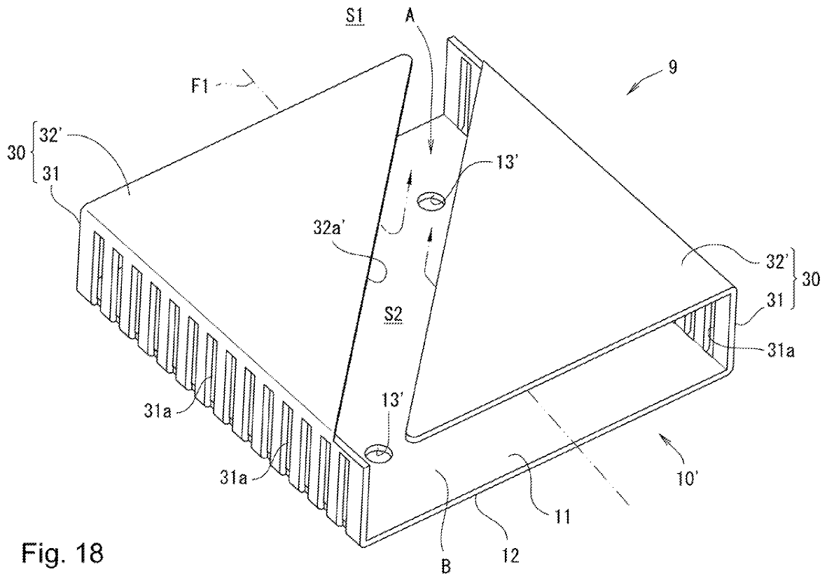

A thirteenth feature is that a penetrating ventilation part is provided in the side wall part (see FIG. 18).

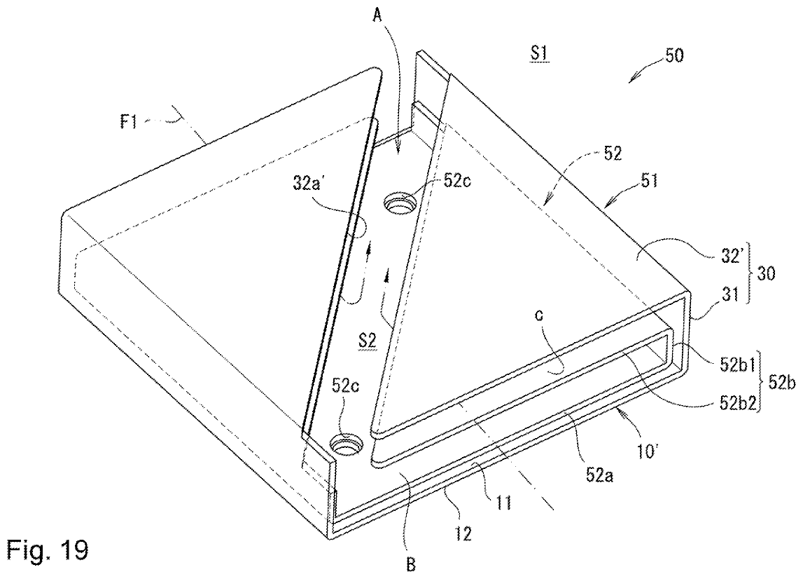

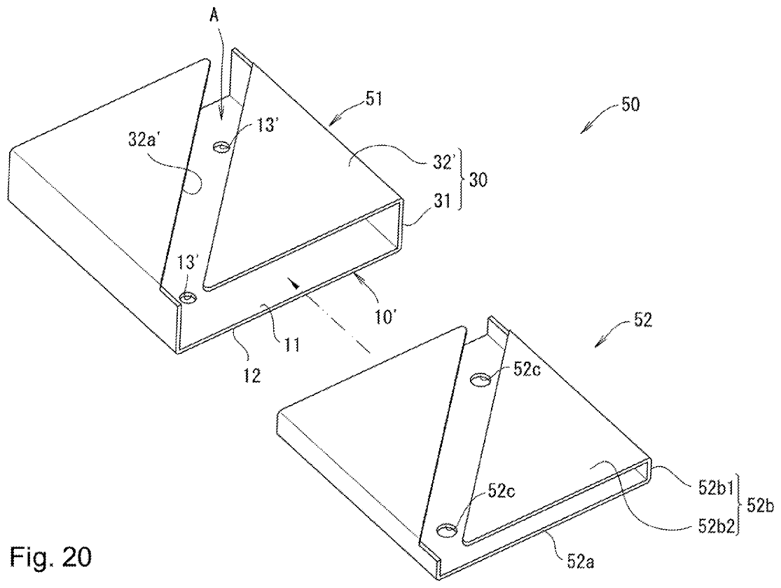

As a fourteenth feature, the aforementioned heat sink serves as a first heat sink and a second heat sink provided in the inner space of the first heat sink, and the second heat sink has a base part and two heat dissipating pieces with substantially the same configuration as those of the base part and the two heat dissipating pieces (see FIGS. 19 and 20).

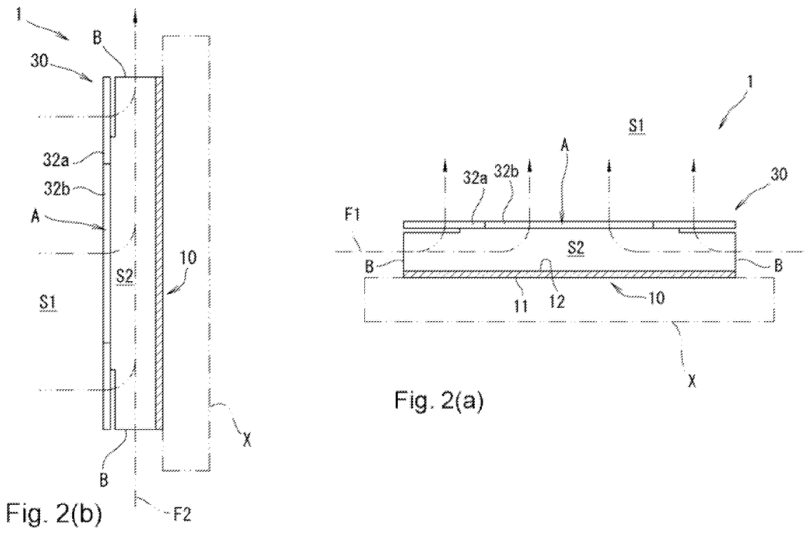

As a fifteenth feature, an electronic component is supported in contact with the electronic component contact surface (see FIGS. 2(a), 2(b), 4(a), 4(b), 6(a), 6(b), 9(a) and 9(b)).

### First Embodiment

Subsequently, a specific embodiment having the aforementioned feature will be described in detail on the basis of the figures.

The heat sink 1 shown in FIGS. 1 to 2(b) includes a plate-shaped base part 10 of which one side surface serves as an electronic component contact surface 11 and the opposite side surface as a heat dissipating surface 12 and two heat dissipating pieces 30 provided on one end side and the other end side in a direction in which the heat dissipating surface 12 continues in the base part 10, and an outer space S1 is configured to communicate with an inner space S2 surrounded by the base part 10 and the heat dissipating pieces 30.

It is to be noted that the heat sink 1 in the illustrated example configures the base part 10 and the two heat dissipating pieces 30, 30 by bending/working a single piece of sheet metal material, but as another example, such a mode is possible that the base part 10 and the heat dissipating pieces 30, 30 which are separate from each other are connected by welding, fitting or the like.

A raw material of this heat sink 1 includes pure metal made of a single metal element, a plurality of metal elements or an alloy made of a metal element and a non-metal element. Here, specific examples of the metal element include aluminum, copper, stainless, nickel, magnesium, and the like.

Moreover, this heat sink 1 may be formed of a single material or may be formed of a composite material in which two or more different materials are integrally combined.

And the heat sink 1 in the illustrated example configures an electronic component package P (see FIG. 1) by bringing the electronic component contact surface 11 into contact with an electronic component X (a CPU, a transistor, a thyristor, other semiconductors, an electronic component, and the like, for example).

The base part 10 is formed in a rectangular flat-plate shape (a quadrate flat-plate shape in the illustrated example), and a surface located on one side (lower side in the illustration) in a thickness direction thereof is formed in a flat state and serves as the electronic component contact surface 11 to be brought into contact with the electronic component X.

The surface on the opposite side (upper side in the illustration) of this base part 10 is formed in a flat state without irregularity, but a heat dissipating fin or the like having an appropriate shape can be provided as necessary.

Reference numeral 13 in FIG. 1 denotes a penetrating mounting hole and is provided in an appropriate number (two on a diagonal line according to this embodiment) on one end side and the other end side on a diagonal line of the base part 10 or on four corner sides and the like. This mounting hole 13 is used for inserting a screw for fastening the base part 10 to the electronic component contact surface 11 or positioning the base part 10 by fitting the base part 10 with a projecting part on the electronic component contact surface 11 side and the like.

Each of the heat dissipating pieces 30 integrally has a side wall part 31 protruding substantially perpendicularly upward from one side of the base part 10 and a top wall part 32 protruding from a tip side of the side wall part 31 toward the other heat dissipating piece 30 substantially in parallel with the heat dissipating surface 12 and ensuring the inner space S2 between itself and the heat dissipating surface 12 and is formed in a substantially inverted L-shape.

The two left and right top wall parts 32, 32 are separated with a space between facing tip parts, and a ventilation path A causing the inner space S2 and the outer space S1 on the upper side to communicate with each other is ensured between the tip parts.

The ventilation path A is formed by a slit part 32a that separates the two top wall parts 32, 32 from each other and a penetrating part 32b (penetrating hole) having a penetrating hole shape across the two top wall parts 32, 32 and a width (inner diameter according to the illustrated example) larger than the slit part 32a.

The slit part 32a is provided in a lengthy state by extending in a direction crossing a direction in which the two top wall parts 32, 32 are aligned. This slit parts 32a are provided in two on both sides with the penetrating part 32b between them.

In addition, the penetrating part 32b is formed in a circular penetrating hole shape by semicircular cut-out parts provided in the one and the other top wall parts 32, 32 (see FIG. 1).

And by means of the aforementioned configuration, an opening part B having a substantially laterally-long rectangular shape on a front view is formed on one end side and the other end side (right end side and left end side in FIG. 2(a)), respectively, in the direction crossing the direction in which the two top wall parts 32, 32 are aligned.

This opening part B functions as an air channel through which air is made to flow between the outer space S1 and the inner space S2.

It is to be noted that reference numeral 32c in the figure denotes a cut-out part for loosely inserting a jig (a driver or the like, for example) for tightening a screw or the like inserted into the mounting hole 13.

In addition, as another example other than the illustrated example, the mounting hole 13 can be even omitted. In this case, the heat dissipating piece 30 may be fixed to the electronic component X by means other than screwing, such as fitting, bonding or the like, for example.

The heat sink 1 configured as above configures the electronic component package by supporting the electronic component X which is a heat source in contact with the electronic component contact surface 11 thereof (see FIGS. 2(a) and 2(b)).

Subsequently, featured working effects of the heat sink 1 configured as above will be described in detail.

As illustrated in FIG. 2(a), in the heat sink 1, when the electronic component contact surface 11 is directed downward and is brought into contact with the electronic component X (hereinafter, referred to as horizontally set), a rising airflow is generated in the ventilation path A by heat of the base part 10, and a continuous flow of air along a two-dot chain line F1 in the illustration is formed such that the air on both of the sides are drawn by this rising airflow.

In more detail, the air in the outer space S1 enters the inner space S2 from opening parts B on both of the sides, passes through the slit part 32a and the penetrating part 32b and flows to the outer space S1 above.

Then, the air flowing as above is brought into contact with the heat dissipating surface 12 of the base part 10 and an inner surface of the heat dissipating piece 30 and performs heat exchange, and suppresses a temperature rise of the base part 10 and the electronic component X.

Moreover, as illustrated in FIG. 2(b), in the heat sink 1, when the electronic component contact surface 11 is directed sideward and is brought into contact with the electronic component X (hereinafter, referred to as vertically set), a rising airflow by the heat of the base part 10 is generated in the inner space S2, and the continuous flow of air along the two-dot chain line F2 in the illustration is formed such that the air on the ventilation path A side and the air on the opening part B side below are drawn by this rising airflow.

In more detail, the air in the outer space S1 enters the inner space S2 from the ventilation path A and the opening part B below, passes through the opening part B above and flows to the outer space S1 above.

Then, the air flowing as above is brought into contact with the heat dissipating surface 12 of the base part 10 and the inner surface of the heat dissipating piece 30 and performs heat exchange, and suppresses the temperature rise of the base part 10 and the electronic component X.

Thus, according to the heat sink 1, with a space-saving and light-weighted structure without a fin or the like protruding to outside, favorable heat dissipating performances can be obtained both in the horizontally set and the vertically set.

Subsequently, other embodiments of the heat sink according to the present invention will be described. The embodiments illustrated below are those obtained by partially changing the aforementioned embodiment and thus, the change parts will be mainly described in detail, while the description on common parts will be omitted as appropriate by using the same reference numerals or the like.

### Second Embodiment

A heat sink 2 illustrated in FIG. 3 has a ventilation hole 33 and a protruding edge part 34 provided on each of the top wall parts 32 with respect to the heat sink 1 configured as above.

The ventilation holes 33 are provided in plural so as to be aligned in a direction in which the surfaces of the top wall parts 32 continue. A gap is ensured between the adjacent ventilation holes 33.

Each of the ventilation holes 33 is formed in a polygonal shape (hexagonal shape according to the illustrated example) and penetrates the top wall part 32 in the thickness direction.

The protruding edge part 34 is provided in a cylindrical shape (hexagonal cylindrical shape according to the illustrated example) protruding from an inner edge side of each of the ventilation holes 33 on the outer surface of the top wall part 32 toward the outer space S1.

This protruding edge parts 34 are disposed in plural so as to correspond to each of the plurality of ventilation holes 33. A gap is ensured between the adjacent protruding edge parts 34. This gap increases a heat dissipating area of the protruding edge part 34.

A protruding amount of each protruding edge part 34 is set approximately to a thickness of the top wall part 32 according to the illustrated example.

Subsequently, featured working effects of the heat sink 2 configured as above will be described in detail.

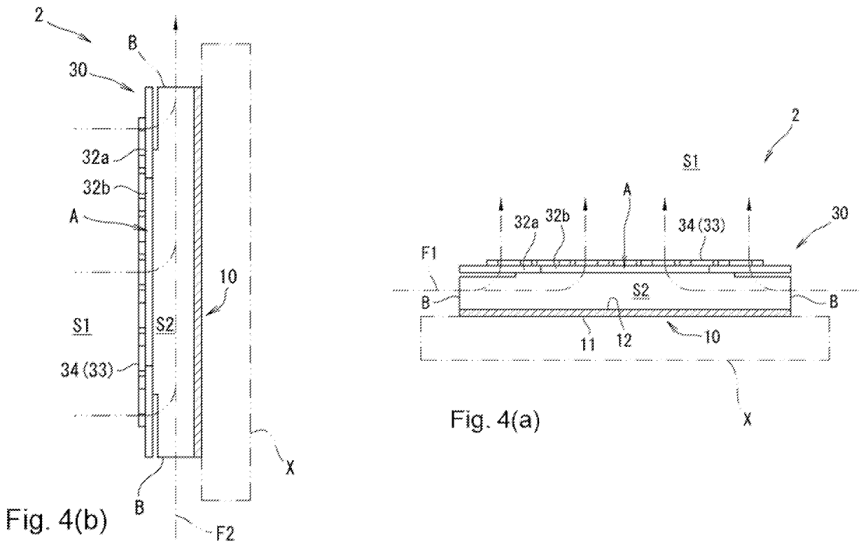

As illustrated in FIG. 4(a), when the heat sink 2 is horizontally set, substantially similarly to the heat sink 1, the continuous flow of air along the two-dot chain line F1 in the illustration is formed.

In more detail, the air in the outer space S1 enters the inner space S2 from the opening parts B on both of the sides, passes through the slit part 32a, the penetrating part 32b, and the ventilation hole 33 and flows into the outer space S1 above.

Then, the air flowing as above is brought into contact with the heat dissipating surface 12 of the base part 10, the inner surface of the heat dissipating piece 30, the inner surfaces of the ventilation hole 33 and the protruding edge part 34 and the like and performs heat exchange, and the heat exchange is performed with air in the outer space S1 also on the outer surface side of the protruding edge part 34 and then, the temperature rise of the base part 10 and the electronic component X is suppressed.

Moreover, as illustrated in FIG. 4(b), when the heat sink 2 is vertically set, too, substantially similarly to the heat sink 1, the continuous flow of air along the two-dot chain line F2 in the illustration is formed.

In more detail, the air in the outer space S1 enters the inner space S2 from the ventilation path A, the ventilation hole 33, and the opening part B below, passes through the opening part B above and flows to the outer space S1 above.

Then, the air flowing as above is brought into contact with the heat dissipating surface 12 of the base part 10, the inner surface of the heat dissipating piece 30, the inner surfaces of the ventilation hole 33 and the protruding edge part 34 and the like and performs heat exchange, the heat exchange is performed with the air in the outer space S1 also on the outer surface side of the protruding edge part 34 and then, the temperature rise in the base part 10 and the electronic component X is suppressed.

Thus, according to the heat sink 2, with the space-saving and light-weighted structure without a fin or the like protruding to the outside, favorable heat dissipating performances can be obtained both in the horizontally set and the vertically set. Moreover, strength of the top wall part 32 can be increased by the ventilation hole 33 and the protruding edge part 34.

### Third Embodiment

A heat sink 3 illustrated in FIG. 5 includes a ventilation hole 35 and a protruding edge part 36 provided on each of the top wall parts 32 with respect to the heat sink 1 configured as above.

The ventilation holes 35 are provided in plural so as to be aligned in a direction in which the surfaces of the top wall parts 32 continue.

Each of the ventilation holes 35 is formed in a polygonal shape (hexagonal shape according to the illustrated example) and penetrates the top wall part 32 in the thickness direction.

The protruding edge part 36 is provided in a cylindrical shape (hexagonal cylindrical shape according to the illustrated example) protruding from the inner edge side of each of the ventilation holes 35 on the outer surface of the top wall part 32 toward the outer space S1.

The protruding edge parts 36 are disposed in plural so as to correspond to the plurality of ventilation holes 35, respectively. The two adjacent protruding edge parts 36, 36 are integrally configured by sharing a wall part 36a located between them. The wall part 36a exerts an action of increasing the strength of the top wall part 32.

The protruding amount of each protruding edge part 36 is set approximately to a thickness of the top wall part 32 according to the illustrated example.

Subsequently, featured working effects of the heat sink 3 configured as above will be described in detail.

As illustrated in FIG. 6(a), when the heat sink 3 is horizontally set, the continuous flow of air along the two-dot chain line F1 in the illustration is formed substantially similarly to the heat sink 1.

In more detail, the air in the outer space S1 enters the inner space S2 from the opening parts B on both of the sides, passes through the slit part 32a, the penetrating part 32b, and the ventilation hole 35 and flows into the outer space S1 above.

Then, the air flowing as above is brought into contact with the heat dissipating surface 12 of the base part 10, the inner surface of the heat dissipating piece 30, the inner surfaces of the ventilation hole 35 and the protruding edge part 36 and the like and performs heat exchange, the heat exchange is performed with the air in the outer space S1 also on the outer surface side of the protruding edge part 36 and then, the temperature rise in the base part 10 and the electronic component X is suppressed.

Moreover, as illustrated in FIG. 6(b), when the heat sink 3 is vertically set, too, substantially similarly to the heat sink 1, the continuous flow of air along the two-dot chain line F2 in the illustration is formed.

In more detail, the air in the outer space S1 enters the inner space S2 from the ventilation path A, the ventilation hole 35, and the opening part B below, passes through the opening part B above, and flows into the outer space S1 above.

Then, the air flowing as above is brought into contact with the heat dissipating surface 12 of the base part 10, the inner surface of the heat dissipating piece 30, the inner surfaces of the ventilation hole 35 and the protruding edge part 36 and the like and performs heat exchange, the heat exchange is performed with the air in the outer space S1 also on the outer surface side of the protruding edge part 36 and then, the temperature rise in the base part 10 and the electronic component X is suppressed.

Thus, according to the heat sink 3, with the space-saving and light-weighted structure without a fin or the like protruding to the outside, favorable heat dissipating performances can be obtained both in the horizontally set and the vertically set. Moreover, strength of the top wall part 32 can be increased by the ventilation hole 35 and the protruding edge part 36.

### Fourth Embodiment

A heat sink 4 illustrated in FIG. 7 has a protrusion 37 protruding to the outer space side provided on each of the top wall parts 32 with respect to the heat sink 1 configured as above.

The protrusions 37 are provided in plural so as to be aligned in a direction in which the surfaces of the top wall parts 32 continue.

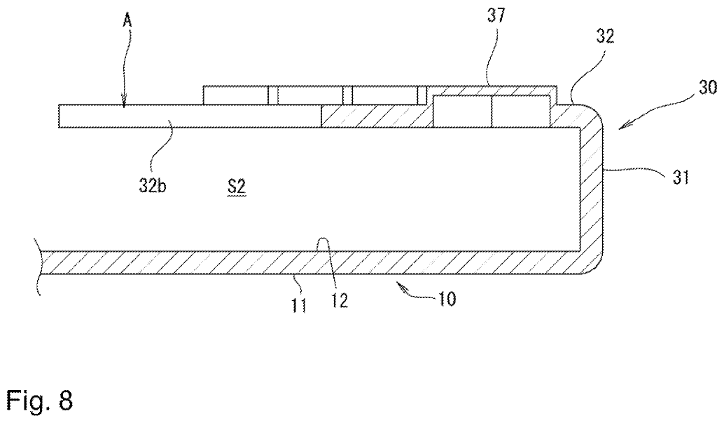

Each of the protrusions 37 is formed in a bottomed tubular shape of a polygonal shape (hexagonal shape according to the illustrated example) having a bottom part on the opposite side to the base part 10 side and protrudes to the outer space S1 side (see FIG. 8).

The protruding amount of each of the protrusions 37 is set substantially to the thickness of the top wall part 32 according to the illustrated example.

A gap is ensured between the adjacent protrusions 37, 37. This gap ensures a heat dissipating area of each protrusion 37 wider.

As another example other than the illustrated examples, the strength of each of the top wall parts 32 can be further improved by integrally connecting the adjacent 37, 37.

Subsequently, featured working effects of the heat sink 4 configured as above will be described in detail.

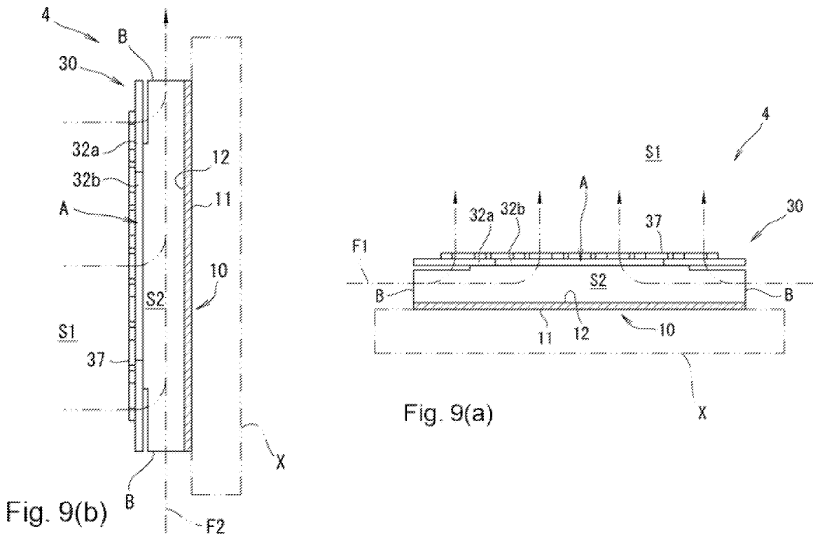

As illustrated in FIG. 9(a), when the heat sink 4 is horizontally set, substantially similarly to the heat sink 1, the continuous flow of air along the two-dot chain line F1 in the illustration is formed.

In more detail, the air in the outer space S1 enters the inner space S2 from the opening parts B on both of the sides, passes through the ventilation path A such as the slit part 32a, the penetrating part 32b and the like, and flows into the outer space S1 above.

Then, the air flowing as above is brought into contact with the heat dissipating surface 12 of the base part 10, the inner surface of the heat dissipating piece 30, the inner surface of the protrusion 37 and the like and performs heat exchange, the heat exchange is performed with the air in the outer space S1 also on the outer surface side of the protrusion 37 and then, the temperature rise in the base part 10 and the electronic component X is suppressed.

Moreover, as illustrated in FIG. 9(b), when the heat sink 4 is vertically set, too, substantially similarly to the heat sink 1, the continuous flow of air along the two-dot chain line F2 in the illustration is formed.

In more detail, the air in the outer space S1 enters the inner space S2 from the ventilation path A and the opening part B below, passes through the opening part B above, and flows into the outer space S1 above.

Then, the air flowing as above is brought into contact with the heat dissipating surface 12 of the base part 10, the inner surface of the heat dissipating piece 30, the inner surfaces of the protrusion 37 and the like and performs heat exchange, the heat exchange is performed with the air in the outer space S1 also on the outer surface side of the protrusion 37 and then, the temperature rise in the base part 10 and the electronic component X is suppressed.

Thus, according to the heat sink 4, with the space-saving and light-weighted structure without a fin or the like protruding to the outside, favorable heat dissipating performances can be obtained both in the horizontally set and the vertically set. Moreover, strength of the top wall part 32 can be increased by the protrusion 37.

<Comparison with Conventional Structure>

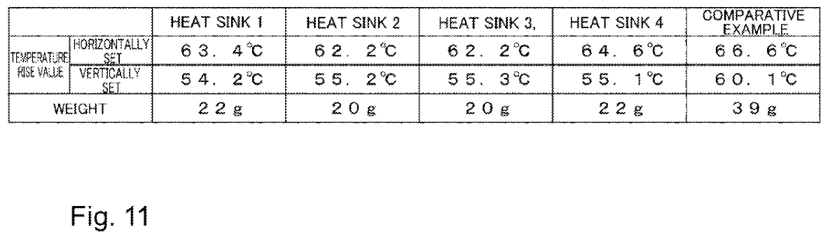

Subsequently, results of comparison in temperature rise values, weights and the like of the base part by computer analysis will be described for the heat sinks 1 to 4 configured as above and a comparative example 100 of a conventional structure (see FIG. 11).

Those with the same appearance dimensions (approximately 60×59×10 mm) were used for the heat sinks 1 to 4 and the comparative example 100.

The comparative example 100 has six heat dissipating fins 120 provided substantially in parallel at intervals on the upper surface of a rectangular base part 110.

As illustrated in a table in FIG. 11, the heat sinks 1 to 4 had temperature rise values lower than that of the comparative example 100 both in the horizontally set and the vertically set, and a remarkably low temperature rise value can be obtained particularly for the vertically set.

Moreover, all the heat sinks 1 to 4 had weights largely lower than that of the comparative example 100.

According to the heat sink 2, the ventilation hole 33 and the protruding edge part 34 are provided as a particularly preferred mode, but the protruding edge part 34 can be omitted as another example, and in this case, too, the ventilation effect by the ventilation hole 33 can be obtained. Similarly, for the heat sink 3, too, the protruding edge part 36 can be omitted.

Moreover, as another example other than the above, there can be a mode in which the ventilation hole 33, the protruding edge part 34, and the protrusion 37 are all disposed on the top wall part 32 of the heat sink 1 and a mode in which the ventilation hole 33, the protruding edge part 34, and the protrusion 37 can be combined as appropriate and disposed and the like.

### Fifth Embodiment

In a heat sink 5 illustrated in FIG. 12, the base part 10 is replaced with a base part 10′ and the top wall part 32 of each heat dissipating piece 30 by a top wall part 32′ with respect to the heat sink 1 configured as above.

In this heat sink 5, the top wall part 32′ of one heat dissipating piece 30 and the top wall part 32′ of the other heat dissipating piece 30 are formed in triangles with hypotenuses facing each other, and the ventilation path A is ensured by a slit part 32a′ formed between the two facing hypotenuses.

The base part 10′ is formed by replacing the mounting hole 13 of the base part 10 with a mounting hole 13′.

The mounting hole 13′ is a penetrating hole and is provided within a range of the ventilation path A on a plane view. In other words, the ventilation path A is located on a center axis of the mounting hole 13′.

When the heat sink 5 configured as above is horizontally set with respect to the electronic component (not shown), substantially similarly to the heat sink 1, an air flow F1 from the opening part B toward the inner space S2 and toward the outer space S1 through the slit part 32a′ is formed. Moreover, in the case of the vertically set, similarly to the heat sink 1 (see FIGS. 2(a) and 2(b)), an air flow entering the inner space S2 from the one opening part B and exiting to the outer space S1 from the other opening part B is formed, and the air entering the inner space S2 from the slit part 32a′ is merged with this flow (not shown).

Thus, according to the heat sink 5 configured as above, the relatively lengthy ventilation path A can be ensured by the inclined slit part 32a′ and then, with the space-saving and light-weighted structure without a fin or the like protruding to the outside, favorable heat dissipating performances can be obtained.

Moreover, when the heat sink 5 is fastened/fixed to the electronic component or the like by a fastening tool (a screw, a bolt and the like, for example) inserted into the mounting hole 13′, the ventilation path A can be used as a space for loosely inserting a jig (a driver and the like, for example) for tightening the fastening tool.

It is to be noted that, in the example illustrated in FIG. 12, the mounting hole 13′ is provided at two locations corresponding to the one end side and the other end side of the ventilation path A (slit part 32a′), but one or three or more may be provided.

### Sixth Embodiment

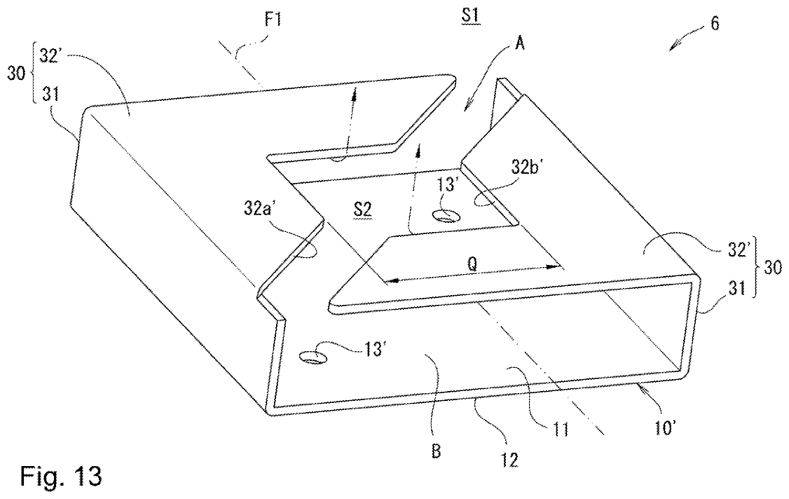

In a heat sink 6 illustrated in FIG. 13, the ventilation path A is configured by the slit part 32a′ and a penetrating part 32b′ by adding the penetrating part 32b′ to the heat sink 5 configured as above.

The penetrating part 32b′ has a substantially quadrate shape on a plane view with a width larger than that of the silt part 32a′ and is provided across the two top wall parts 32′, 32′.

Regarding this heat sink 6, the flow F1 of the air in the case of the horizontally set and the flow of the air in the case of the vertically set (not shown) are substantially similar to the aforementioned heat sink 1 and the heat sink 5 and the like.

Thus, according to the heat sink 6 configured as above, the ventilation path A with a large flowing area can be ensured by the inclined slit part 32a′ and the penetrating part 32b′ and then, with the space-saving and light-weighted structure without a fin or the like protruding to the outside, favorable heat dissipating performances can be obtained.

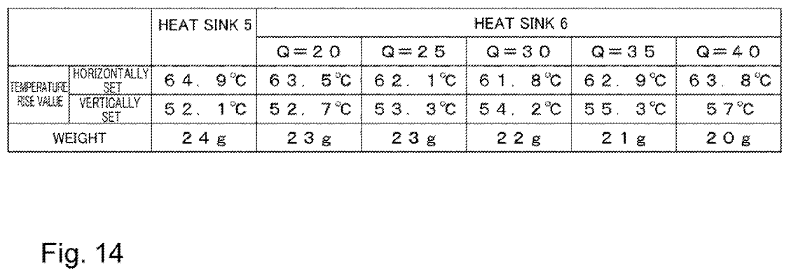

Subsequently, results of comparison in temperature rise values, weights and the like of the base part by computer analysis will be described for the heat sinks 5 and 6 configured as above (see FIG. 14).

The appearance dimensions of the sample used for this experiment were approximately 60×59×10 mm) for all.

The experiment was conducted for five types of samples with different dimension Q of one side of the substantially quadrate penetrating part 32b′ for the heat sink 6 as illustrated in the table in FIG. 14.

As illustrated in the table in FIG. 14, the temperature rise value in the case of the horizontally set rose as the dimension Q became larger, became minimum at Q=30 mm, and rose when Q became further larger.

Moreover, it was confirmed that the temperature rise value in the case of the vertically set rose as the dimension Q became larger up to Q=40 mm.

From these results, in the case of use in the horizontally set, the dimension Q=30 mm is preferable, while in the case of use in the vertically set, the dimension Q=40 mm is preferable.

### Seventh Embodiment

A heat sink 7 illustrated in FIG. 15 has a ventilation hole 33′ and a protruding edge part 34′ provided in the top wall part 32′ in the heat sink 5 configured as above.

The ventilation holes 33′ are provided in plural at predetermined intervals along the surface of each of the top wall parts 32′. Each of the ventilation holes 33′ penetrates the top wall part 32′ in the thickness direction as illustrated in FIG. 16(a).

The protruding edge part 34′ is configured substantially cylindrically by protruding from the entire inner edge of the ventilation hole 33′ toward the inner space S2.

When this heat sink 7 is horizontally set to the electronic component (not shown), substantially similarly to the heat sink 2, a flow of air which enters the inner space S2 from the opening part B, passes through the slit part 32a′ and exits to the outer space S1 and a flow of air which enters the inner space S2 from the opening part B, passes through the ventilation hole 33′ and exits to the outer space S1 are formed (see the two-dot chain line F1 in FIG. 15).

Moreover, in the case of the vertically set, similarly to the heat sink 2 and the like, a flow of air which enters the inner space S2 from the one opening part B and exits to the outer space S1 from the other opening part B is formed, and air which enters the inner space S2 from the slit part 32a′ merges with this flow and moreover, air which enters the inner space S2 from the ventilation hole 33′ also merges with that (not shown).

Thus, according to the heat sink 7 configured as above, the space-saving and light-weighted structure without a fin or the like protruding to the outside can be obtained and moreover, a ventilation amount and the heat dissipating area can be largely ensured by the inclined slit part 32a′, the ventilation hole 33′, the protruding edge part 34′ and the like, and favorable heat dissipating performances can be obtained.

It is to be noted that, in the heat sink 7 configured as above, a part of or the whole of the ventilation hole 33′ and the protruding edge part 34′ can be replaced with a protrusion 37′ illustrated in FIG. 16(b). The protrusion 37′ is formed in a bottomed tubular shape with a bottom part on the base part side and protrudes to the inner space S2 side.

According to the heat sink including this protrusion 37′, a space-saving and light-weighted structure without a fin or the like protruding to the outside can be obtained and moreover, working effects such as increased strength of the top wall part 32′, improvement of the heat dissipating performance and the like can be obtained by the protrusion 37′.

Moreover, as another example, in the heat sink 7, a part of or the whole of the ventilation hole 33′ and the protruding edge part 34′ or the protrusion 37′ and the like can be replaced with the aforementioned hexagonal ventilation hole 33 and the protruding edge part 34 or the protrusion 37 and the like.

### Eighth Embodiment

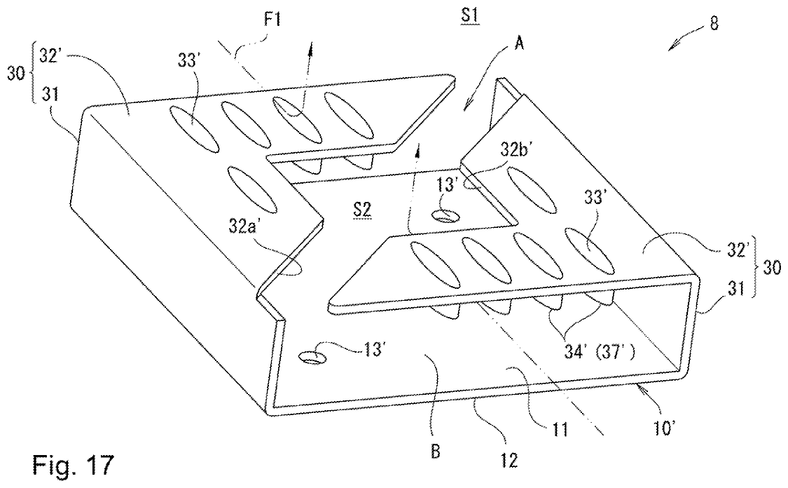

The heat sink 8 illustrated in FIG. 17 has the ventilation holes 33′ and the protruding edge parts 34′ provided in plural on the top wall part 32′ in the heat sink 6 configured as above.

The ventilation hole 33′ and the protruding edge part 34′ have the same structure as that of the heat sink 7 (see FIG. 16(a)).

According to this heat sink 8, the ventilation amount and the heat dissipating area can be ensured largely by the inclined slit part 32a′, the penetrating part 32b, the ventilation hole 33′, the protruding edge part 34′ and the like and then, with the space-saving and light-weighted structure without a fin or the like protruding to the outside, favorable heat dissipating performances can be obtained.

It is to be noted that, in this heat sink 8, too, the ventilation hole 33′ and the protruding edge part 34′ can be replaced with the protrusion 37′ (see FIG. 16(b)).

### Ninth Embodiment

A heat sink 9 illustrated in FIG. 18 has a plurality of ventilation parts 31a formed on the side wall part 31 in the heat sink 5 configured as above.

The ventilation part 31a is a slit-like penetrating hole which is lengthy to a protruding direction (above in the illustrated example) of the side wall part 31, and they are provided in plural at intervals in a crossing direction to the protruding direction.

In the heat sink 9, in addition to that a flow of air passing through the slit part 32a′ and the opening part B can be formed, a flow of air passing through the ventilation parts 31a of each side wall part 31 can be also formed and then, with the space-saving and light-weighted structure without a fin or the like protruding to the outside, favorable heat dissipating performances can be obtained.

### Tenth Embodiment

A heat sink 50 illustrated in FIGS. 19 and 20 is formed by having the heat sink 5 (see FIG. 12) as a first heat sink 51 and by providing a second heat sink 52 in an inner space of this first heat sink 51.

The second heat sink 52 has substantially the same configuration as those of the base part 10 and the heat dissipating piece 30 of the heat sink 5, has a base part 52a and a heat dissipating piece 52b which are slightly smaller, and is in contact with the base part 10′ of the first heat sink 51.

The base part 52a is formed in a rectangular flat-plate shape slightly smaller than the base part 10′ and is in contact with the heat dissipating surface 12 of the base part 10′.

In this base part 52a, a mounting hole 52c is provided so as to communicate with each mounting hole 13′ of the base part 10′.

The heat dissipating piece 52b is formed in a substantially inverted L-shape integrally having a side wall part 52b1 and a top wall part 52b2 substantially similarly to the heat dissipating piece 30 of the heat sink 5.

A gap c through which air can flow is ensured between the top wall part 32′ of the first heat sink 51 and the top wall part 52b2 of the second heat sink 52.

In the heat sink 50 configured as above, an air channel from the opening part B over the slit part 32a′ is formed in the gap c and the second heat sink 52 and a wider heat dissipating area can be ensured by the two heat sinks 51, 52 and then, with the space-saving and light-weighted structure without a fin or the like protruding to the outside, favorable heat dissipating performances can be obtained.

It is to be noted that the second heat sink 52 may be integrated to the first heat sink 51 in advance by welding or the like, but as another example, the second heat sink 52 may be assembled to the first heat sink 51 as necessary.

Moreover, in the aforementioned embodiment, the base part 52a of the second heat sink 52 is brought into contact with the base part 10′ of the first heat sink 51, but as another example, such a mode in which a gap is provided between these base parts 52a, 10′ can be realized. In this case, it is only necessary to connect the side wall part 52b1 of the second heat sink 52 to the side wall part 31 of the first heat sink 51 by welding or the like, for example.

Moreover, the penetrating part 32b′, the ventilation hole 33′ and the protruding edge part 34′, the protrusion 37′, the ventilation part 31a and the like can be disposed as appropriate on the first heat sink 51 and the second heat sink 52 of the heat sink 50 similarly to the heat sinks 7 and 8 (see FIGS. 15 to 17).

Moreover, the present invention is not limited to the aforementioned embodiments but can be changed as appropriate within a range not changing the gist of the present invention.

### REFERENCE SIGNS LIST

1, 2, 3, 4, 5, 6, 7, 8, 9, 50: Heat sink
10, 10′: Base part
11: Electronic component contact surface
12: Heat dissipating surface
13′: Mounting hole
30: Heat dissipating piece
31: Side wall part
32, 32′: Top wall part
32a, 32a′: Slit part
32b, 32b′: Penetrating part
33, 33′, 35: Ventilation hole
34, 34′, 36: Protruding edge part
37, 37′: Protrusion
51: First heat sink
52: Second heat sink
52a: Base part
52b: Heat dissipating piece
A: Ventilation path
B: Opening part
S1: Outer space
S2: Inner space

1. A heat sink comprising:
a base part of which one side surface serves as an electronic component contact surface and the opposite side surface as a heat dissipating surface; and
two heat dissipating pieces provided on one end side and the other end side in a direction in which the heat dissipating surface continues in the base part, wherein
each of the two heat dissipating pieces has a side wall part protruding from the heat dissipating surface and a top wall part protruding from a tip side of the side wall part toward the other heat dissipating piece and ensuring an inner space between the top wall part and the heat dissipating surface; and
two of the top wall parts are separated such that a ventilation path causing the inner space and an outer space to communicate with each other is ensured therebetween.

2. The heat sink according to claim 1, wherein the ventilation path includes a slit part between the two top wall parts.

3. The heat sink according to claim 2, wherein the ventilation path includes a penetrating part which has a penetrating hole shape across the two top wall parts and a width larger than the slit part.

4. The heat sink according to claim 1, wherein a ventilation hole which penetrates the top wall part in a thickness direction is provided in at least one of the two top wall parts.

5. The heat sink according to claim 4, wherein a protruding edge part protruding toward the outer space is provided on an inner edge side of the ventilation hole.

6. The heat sink according to claim 4, wherein a protruding edge part protruding toward the inner space is provided on an inner edge side of the ventilation hole.

7. The heat sink according to claim 5, wherein
the ventilation holes and the protruding edge parts are provided in plural on each of the top wall parts, and
the two adjacent protruding edge parts are disposed with a gap.

8. The heat sink according to claim 5, wherein
the ventilation holes and the protruding edge parts are provided in plural on each of the top wall parts, and
the two adjacent protruding edge parts are integrally configured by sharing a wall part located therebetween.

9. The heat sink according to claim 1, wherein
a plurality of protrusions protruding to the outer space side are provided on at least one of the two top wall parts, and
each of the protrusions is formed in a bottomed tubular shape with a bottom part on the opposite side to the base part side.

10. The heat sink according to claim 1, wherein
a plurality of protrusions protruding to the inner space side are provided on at least one of the two top wall parts, and
each of the protrusions is formed in a bottomed tubular shape with a bottom part on the base part side.

11. The heat sink according to claim 1, wherein
a penetrating mounting hole is provided in the base part; and
the mounting hole is provided within a range of the ventilation path on a plane view.

12. The heat sink according to claim 1, wherein
the top wall part of one heat dissipating piece and the top wall part of the other heat dissipating piece in the two heat dissipating pieces are formed in triangles with hypotenuses facing each other, and
the ventilation path is ensured between the two hypotenuses facing each other.

13. The heat sink according to claim 1, wherein a penetrating ventilation part is provided in the side wall part.

14. A heat sink comprising:
the heat sink according to claim 1 serving as a first heat sink and a second heat sink provided in an inner space of the first heat sink, wherein the second heat sink has a base part and two heat dissipating pieces with substantially the same configuration as those of the base part and the two heat dissipating pieces.

15. An electronic component package using the heat sink according to claim 1, wherein an electronic component is supported in contact with the electronic component contact surface.

16. The heat sink according to claim 6, wherein
the ventilation holes and the protruding edge parts are provided in plural on each of the top wall parts, and
the two adjacent protruding edge parts are disposed with a gap.

17. The heat sink according to claim 6, wherein
the ventilation holes and the protruding edge parts are provided in plural on each of the top wall parts, and
the two adjacent protruding edge parts are integrally configured by sharing a wall part located therebetween.
